(19) United States
(12) Patent Application Publication
(10) Pub. No.: US 2010/0054071 A1
(43) Pub. Date: Mar. 4, 2010

(54) SEMICONDUCTOR MEMORY DEVICE

(76) Inventor: Takafumi MARUYAMA, Osaka (JP)

Correspondence Address: MCDERMOTT WILL & EMERY LLP, 600 13TH STREET, NW, WASHINGTON, DC, 20005-3096, US

(21) Appl. No.: 12/512,475

(22) Filed: Jul. 30, 2009

(30) Foreign Application Priority Data
Sep. 1, 2008 (JP) 2008-223891

(51) Int. Cl. G11C 5/14; G11C 8/00

(52) U.S. Cl. 365/226; 365/230.03

(57) ABSTRACT

A semiconductor memory device is provided which has a memory cell region in which a plurality of memory cells are arranged in a matrix. The memory cell region is divided into a plurality of sectors each including a predetermined number of rows. Main bit lines extending in a column direction have an intersecting region between the sectors in which the main bit lines intersect at one or more points. The semiconductor memory device is configured to be able to supply different voltages to neighbor ones of the main bit lines in each of the sectors.

### CROSS REFERENCE TO RELATED APPLICATIONS

This application claims priority under 35 U.S.C. §119(a) on Patent Application No. 2008-223891 filed in Japan on Sep. 1, 2008, the entire contents of which are hereby incorporated by reference.

### BACKGROUND

The present disclosure relates to a semiconductor memory device having a memory array arrangement which has been developed to achieve a goal of reducing coupling noise between main bit lines by intersecting the main bit lines. More particularly, the present disclosure relates to a technique of detecting a leakage current passing between the main bit lines.

A virtual ground memory array (VGA) arrangement, which can have a considerably high level of area efficiency, has been used as a technique of achieving a large-capacity memory (see, for example, U.S. Pat. No. 6,351,415 B1 (particularly, FIG. 4)). Also, a technique has been proposed which applies a voltage to the source of a neighbor cell so as to prevent a leakage of a cell current into the neighbor cell due to a common drain/source which is a characteristic feature of the VGA arrangement (hereinafter such a leakage is referred to as a neighbor effect) (see, for example, US 2005/0088878 A1 (particularly, FIG. 5B)).

Such a VGA arrangement generally has a hierarchical bit line arrangement including main bit lines and sub-bit lines. Alternatively, an arrangement in which main bit lines intersect in a memory array may be employed so as to further reduce coupling noise between neighbor main bit lines during read operation as shown in FIG. 6.

### SUMMARY

However, it was found that, in conventional memory array arrangements in which main bit lines intersect, when a main bit line leakage test of detecting an initial short-circuit failure is performed in a specific selected state, the short-circuit failure may fail to be detected.

Operation which fails to detect a short-circuit failure between neighbor main bit lines when the main bit line leakage test is performed, will be described with reference to FIG. 6. FIG. 7 is an example diagram showing details of a memory array region 10 in FIG. 6 (a memory array region 11 is alike). A plurality of word lines WL from a row selecting circuit 12 of FIG. 6 and a plurality of select lines SEL from a select line selecting circuit 13 of FIG. 6 for controlling connection between main bit lines MBL and sub-bit lines DBL are connected to the memory array region 10 of FIG. 7.

Initially, operation of the main bit line leakage test will be briefly described using a memory array arrangement of FIG. 5 in which main bit lines do not intersect.

There are two methods of performing the main bit line leakage test: (1) a method of selecting and testing each pair of neighbor main bit lines so as to increase the detection sensitivity; and (2) a method of simultaneously selecting and testing a batch of main bit line pairs so as to decrease a time required for the test (batch process). Here, a case where each pair of neighbor main bit lines is selected and tested will be mainly described, although there is also a non-detected pattern when a batch process is performed, which could be inferred from the analogy of a description below.

According to FIG. 5, it is assumed, during normal read operation, the main bit lines MBL0, MBL2, MBL4 and MBL6 are connected to the drains of the memory cells, while the main bit lines MBL1, MBL3, MBL5 and MBL7 are connected to the source of the memory cells.

Although it is assumed that a bit line voltage applying section 15 for supplying a drain voltage to a memory cell during normal read operation is also used to perform the main bit line leakage test, another voltage applying section can be additionally used for the leakage test. It is also assumed that the bit line voltage applying section 15 can supply a desired voltage in addition to the drain voltage.

When the main bit line leakage test is performed with respect to each pair of neighbor main bit lines, a column selecting circuit 14 causes two of column selecting transistors CT0 to CT7 to be in the conductive state by selecting two of column selecting transistor select signals CS0 to CS7 corresponding to the two transistors in accordance with a supplied address. For example, when the leakage test is performed between a main bit line pair MBL0 and MBL1, the column selecting transistor select signals CS0 and CS1 are caused to take a logical value of “1” (i.e., CS0 and CS1 are selected), whereby the column selecting transistors CT0 and CT1 are caused to be in the conductive state. The bit line voltage applying section 15 supplies a drain voltage to the main bit line MBL0. And a control signal TCTL0 is caused to take a logical value of “1” (i.e., TCTL0 is selected), so that the main bit line MBL1 connected to the source of a memory cell and a test terminal are caused to be in the conductive state via a switch SW0. Thereafter, the test terminal is set to be at a ground voltage using an external tester, whereby a leakage can be detected between the main bit line pair MBL0 and MBL1.

Similarly, leakage detection can be performed with respect to the other main bit line pairs by selecting the corresponding column selecting transistor select signals.

However, when a memory array arrangement in which main bit lines intersect as shown in FIG. 6 is employed, a short-circuit failure between main bit line pairs may fail to be detected.

For example, as is similar to the description with reference to FIG. 5, when the leakage test is performed between the main bit line pair MBL0 and MBL1, the column selecting transistor select signals CS0 and CS1 are caused to take a logical value of “1” (i.e., CS0 and CS1 are selected), so that the column selecting transistors CT0 and CT1 are caused to be in the conductive state. The bit line voltage applying section 15 supplies a drain voltage to the main bit line MBL0. And the control signal TCTL0 is caused to take a logical value of “1” (i.e., TCTL0 is selected), so that the main bit line MBL1 connected to the source of a memory cell and the test terminal are caused to be in the conductive state via the switch SW0. Thereafter, the test terminal is set to be at a ground voltage using an external tester, whereby a leakage can be detected between the main bit line pair MBL0 and MBL1.

In this case, a leakage between neighbor main bit lines can be detected for main bit lines provided in the memory array region 11 closer to the column selecting transistors CT0 to CT7, as is similar to the description with reference to FIG. 5. However, since main bit lines provided in the memory array region 10 farther from the column selecting transistors CT0 to CT7 intersect, MBL2 and MBL3 neighbor the main bit line MBL0. In this case, a drain voltage is supplied from the bit line voltage applying section 15 to the main bit line MBL0 since the column selecting transistor CT0 is in the conductive state, while the main bit line MBL2 is in the floating state since the column selecting transistor CT2 is not in the conductive state. As a result, a leakage detection path is not formed. Therefore, even if there is a short-circuit failure between the main bit lines MBL0 and MBL2 in the memory array region 10, the short-circuit failure is not detected.

A case where a batch of main bit lines are simultaneously selected and tested will also be described. For example, all of the column selecting transistors CT0 to CT7 are caused to be in the conductive state, and a drain voltage is supplied to the main bit lines MBL0, MBL2, MBL4 and MBL6 by the bit line voltage applying section 15, thereby causing the main bit lines MBL1, MBL3, MBL5 and MBL7 and the test terminal to be in the conductive state via the switch SW0. Thereafter, the test terminal is set to be at a ground voltage using an external tester, thereby performing leakage detection. In this case, the main bit lines MBL0 and MBL2 have the same potential. Therefore, even if there is a short-circuit failure between the main bit lines MBL0 and MBL2 in the memory array region 10, the short-circuit failure is not detected.

Similarly, even if there is a short-circuit failure between the main bit line pair MBL1 and MBL3, MBL4 and MBL6, or MBL5 and MBL7 provided in the memory array region 10, the short-circuit failure cannot be detected, since one of the main bit lines in the pair is in the floating state in the method of selecting and testing each pair of neighbor main bit lines, and the main bit lines in each pair have the same potential in the method of simultaneously selecting and testing a batch of main bit line pairs.

An object of the present disclosure is to provide a semiconductor memory device having a memory array arrangement in which a plurality of main bit lines intersect, where a leakage current between neighbor main bit lines can be easily detected.

To achieve the object, the present disclosure provides a semiconductor memory device having a memory array arrangement in which main bit lines intersect, where a circuit is configured to apply different potentials to neighbor main bit lines.

An overview of representative embodiments of the present disclosure will be briefly described as follows.

A semiconductor memory device according to a first embodiment has a memory cell region in which a plurality of memory cells are arranged in a matrix extending in a row direction and in a column direction. The memory cell region is divided into a plurality of sectors each including a predetermined number of rows. The device includes a column selecting circuit for selecting a column in the memory cell region, a row selecting circuit for selecting a row in the memory cell region, a plurality of word lines provided for respective rows of the memory cells and connected to the row selecting circuit, a plurality of main bit lines extending in the column direction and connected to respective column selecting transistors controlled by the column selecting circuit, a plurality of sub-bit lines provided in each of the sectors and extending in the column direction, a plurality of selecting transistors provided for the respective sub-bit lines, for electrically connecting or disconnecting the respective main bit lines and the respective sub-bit lines, a plurality of select lines extending in the row direction, for applying a voltage for switching conductive and non-conductive states of the respective selecting transistors, to control electrodes of the respective selecting transistors, and a select line selecting circuit for driving the select lines. The row selecting circuit selects a word line connected to a memory cell to be read out. The plurality of main bit lines have an intersecting region between the sectors, the plurality of main bit lines intersecting at one or more points in the intersecting region. The semiconductor memory device is configured to be able to supply different voltages to neighbor ones of the main bit lines in each of the sectors.

According to the first embodiment, even in a semiconductor memory device having a memory array arrangement in which a plurality of main bit lines intersect, it is possible to easily detect a leakage current between neighbor main bit lines.

According to the present disclosure, in a semiconductor memory device having a memory array arrangement in which a plurality of main bit lines intersect, different voltages can be supplied to neighbor main bit lines, thereby easily detecting a leakage current between the main bit lines. As a result, the product quality of the semiconductor memory device can be improved.

### BRIEF DESCRIPTION OF THE DRAWINGS

FIG. 1 is a diagram showing an arrangement of a semiconductor memory device according to a first embodiment.

FIG. 2 is a diagram showing an arrangement of the semiconductor memory device of the first embodiment.

FIG. 3 is a diagram showing an arrangement of a semiconductor memory device according to a second embodiment.

FIG. 4 is a diagram showing a voltage waveform for indicating leakage detecting operation in the semiconductor memory device of the second embodiment.

FIG. 5 is a diagram showing an arrangement of a conventional semiconductor memory device (main bit lines do not intersect).

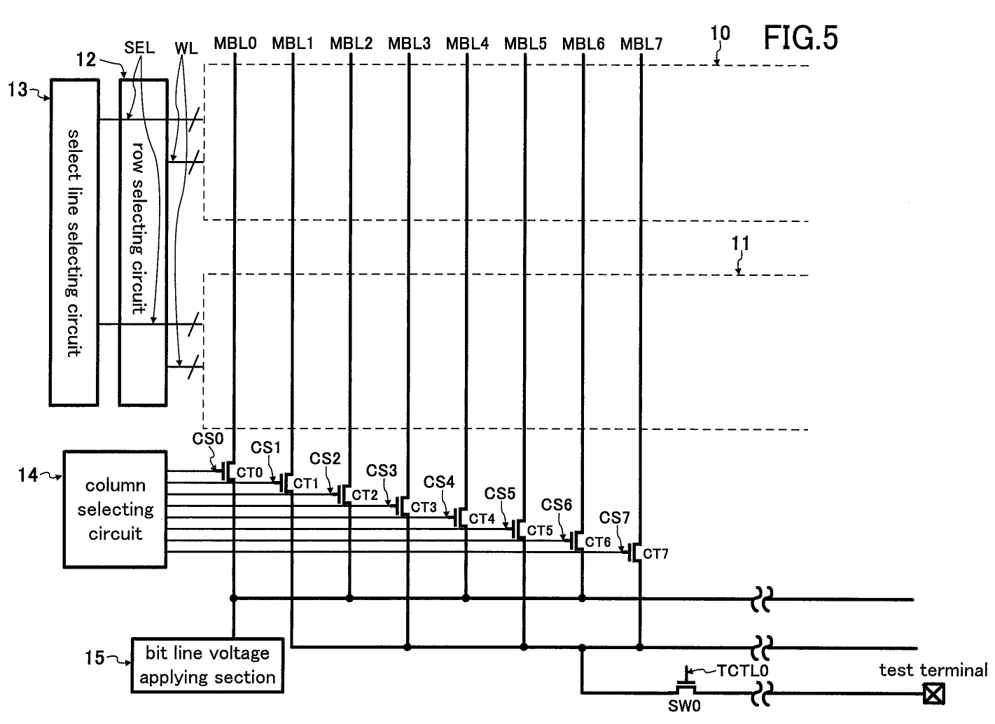

FIG. 6 is a diagram showing an arrangement of a conventional semiconductor memory device (main bit lines intersect).

FIG. 7 is a diagram showing details of a memory array region.

### DETAILED DESCRIPTION

Firstly, an overview of an example semiconductor memory device according to the present disclosure will be described. A well-known memory cell in a semiconductor memory device has a structure in which a floating gate is interposed between a substrate and a control gate. The memory cell holds binary information, depending on whether or not electrons are accumulated in the floating gate. When electrons are accumulated in the floating gate, the threshold of a gate voltage applied to the control gate is high. Therefore, in this case, even if a predetermined gate voltage is applied, substantially no current passes through the memory cell. This state is assumed to mean that “0” is stored. Conversely, when electrons are not accumulated, the gate voltage threshold is low. Therefore, in this case, if the predetermined gate voltage is applied to the control gate, a current passes through the memory cell. This state is assumed to mean that “1” is stored. Here, it is assumed that a state in which electrons are not accumulated is an erased state “1” and a state in which electrons are accumulated is a written state “0”.

The present disclosure is also effective not only to a memory cell having a floating gate, but also to a MONOS memory cell in which electric charge is accumulated in a trap of a nitride film (insulating film) interposed between oxide films to hold data, a non-volatile memory (e.g., a mask ROM, etc.), and the like.

The present disclosure is also effective to an array arrangement having a layout which has a hierarchical bit line arrangement having main and sub-bit lines and in which the main bit lines intersect.

### First Embodiment

Hereinafter, an overview of a semiconductor memory device according to a first embodiment of the present disclosure will be described with reference to the drawings. The semiconductor memory device of this embodiment is additionally provided with a selecting circuit and a selecting transistor for a main bit line leakage test, and a voltage applying section, thereby making it possible to easily detect a leakage current between neighbor main bit lines.

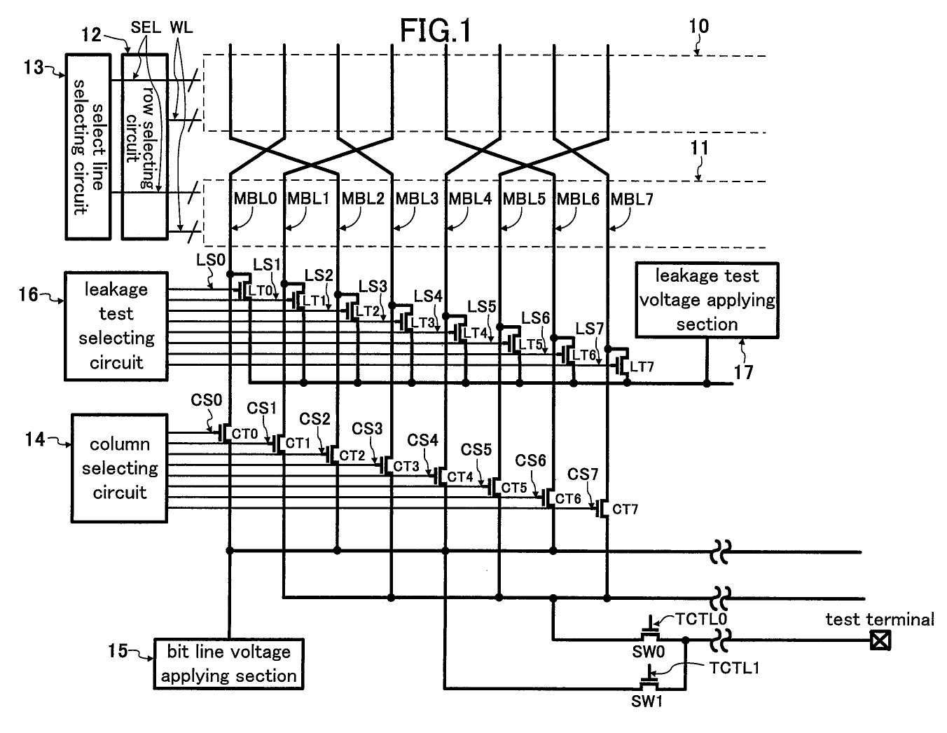

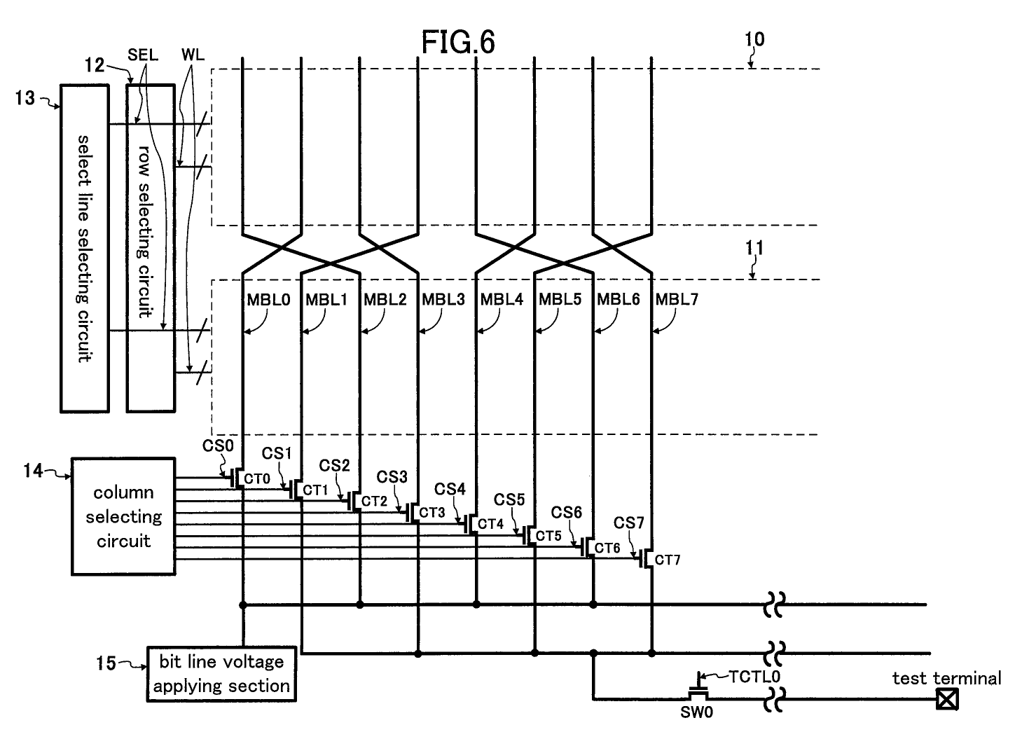

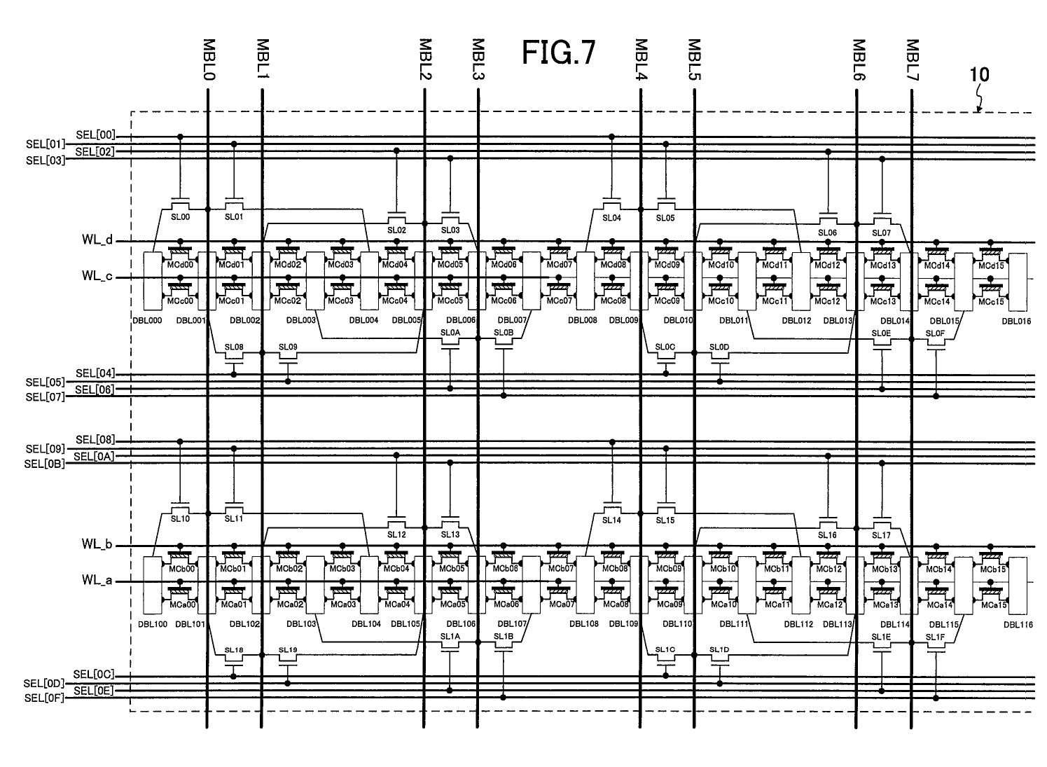

FIG. 1 is a diagram showing an arrangement of the semiconductor memory device of the first embodiment of the present disclosure. The arrangement of FIG. 1 is basically obtained by adding, to the arrangement of FIG. 6, a selecting circuit 16 for the leakage test (switch circuit selecting circuit), a voltage applying section 17 for the leakage test (voltage applying section), selecting transistors LT0 to LT7 (switch circuits) for the leakage test and for connecting the leakage test voltage applying section 17 and respective main bit lines MBL0 to MBL7, selecting transistor select signals LS0 to LS7 for the leakage test, a switch SW1 provided between the main bit lines MBL0, MBL2, MBL4 and MBL6 and a test terminal, and a control signal TCLT1 for the switch SW1. Details of memory array regions 10 and 11 (sectors) are shown in FIG. 7.

In the arrangement of FIG. 1, the main bit line leakage test is performed in the following two steps:

1: a leakage test for main bit lines in the memory array region 11; and

2: a leakage test for main bit lines in the memory array region 10.

Step 1, i.e., a method of testing a leakage between main bit lines provided in the memory array region 11 closer to the column selecting transistors CT0 to CT7, is similar to the conventional example and therefore will not be described. In this case, the leakage test selecting transistors LT0 to LT7 and the switch SW1 are in the non-conductive state, and the leakage test voltage applying section 17 is in the inactive state.

Hereinafter, step 2 in which a short-circuit failure may fail to be detected as described above will be described. Here, as an example, a method of testing a leakage between a pair of main bit lines MBL0 and MBL2 will be mainly described, although it could be easily inferred from the analogy of the following description that the method is also applicable to the other bit line pairs which have not yet been detected.

In step 2, the bit line voltage applying section 15 is caused to be in the inactive state, while the leakage test voltage applying section 17 is caused to be in the active state. In this situation, the column selecting transistor select signal CS0 and the leakage test selecting transistor select signal LS2 are caused to take a logical value of “1” (i.e., CS0 and LS2 are selected), so that the column selecting transistor CT0 and the leakage test selecting transistor LT2 are caused to be in the conductive state. The leakage test voltage applying section 17 supplies to a desired voltage to the main bit line MBL2. And the control signal TCTL1 is caused to take a logical value of “1” (i.e., TCTL1 is selected), so that the main bit line MBL0 connected to the source of a memory cell and the test terminal are caused to be in the conductive state via the switch SW1. Thereafter, the test terminal is set to be at a ground voltage using an external tester, whereby a leakage can be detected between the main bit line pair MBL0 and MBL2.

Also, a case where a batch of main bit line pairs are simultaneously selected and tested will be described. Initially, the bit line voltage applying section 15 is caused to be in the inactive state, while the leakage test voltage applying section 17 is cause to be in the active state. In this situation, for example, the column selecting transistors CT0 and CT4 and the leakage test selecting transistors LT2 and LT6 are caused to be in the conductive state, while a desired voltage is supplied to the main bit lines MBL2 and MBL6 by the leakage test voltage applying section 17, and the main bit lines MBL0 and MBL4 and the test terminal are caused to be in the conductive state via the switch SW1. Thereafter, the test terminal is set to be at a ground voltage using an external tester. As a result, a leakage can be detected between the main bit lines MBL0 and MBL2 and between MBL4 and MBL6.

Similarly, the column selecting transistors CT1 and CT5 and the leakage test selecting transistors LT3 and LT7 are caused to be in the conductive state, and a desired voltage is supplied to the main bit lines MBL3 and MBL7 by the leakage test voltage applying section 17, and the main bit lines MBL1 and MBL5 and the test terminal are caused to be in the conductive state via the switch SW0. Thereafter, the test terminal is set to be at a ground voltage using an external tester. As a result, a leakage can be detected between the main bit lines MBL1 and MBL3 and between MBL5 and MBL7.

Thus, by using the arrangement of this embodiment, a short-circuit failure existing in the memory array region 10, which cannot be conventionally detected, can be easily detected.

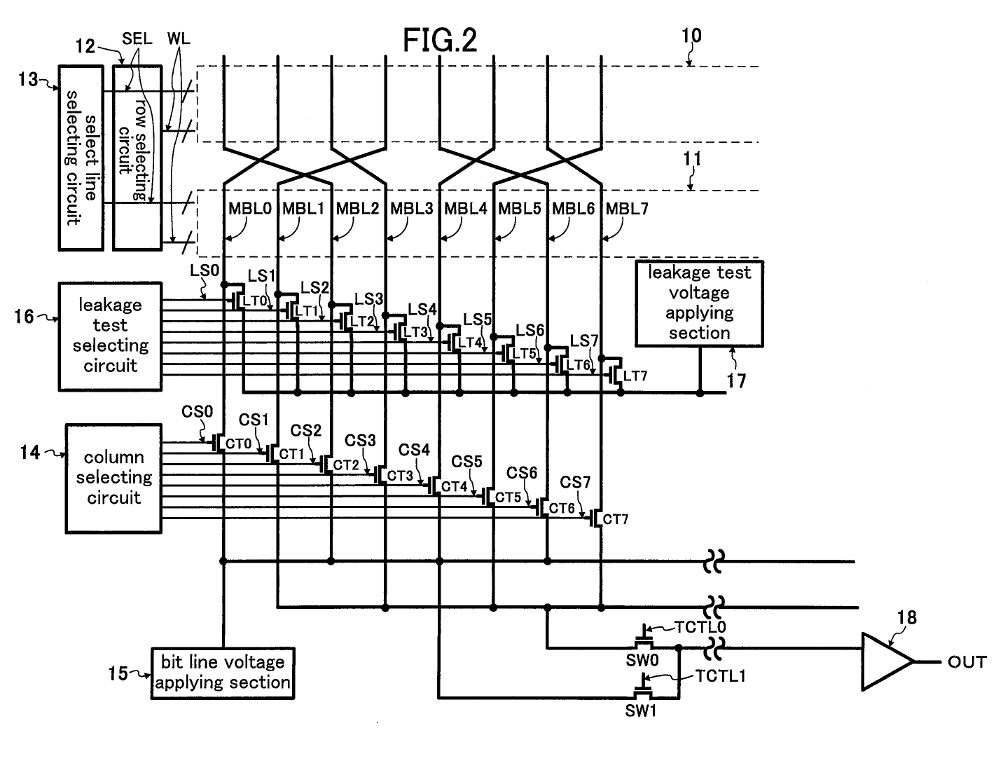

Although the method of detecting a leakage current passing through the test terminal connected to the outside using an external tester has been described above, the detection method is not limited to this. For example, as shown in FIG. 2, a leakage current detecting circuit 18 may be provided in a chip to detect the presence or absence of a leakage using its out OUT. Alternatively, a sense amplifier circuit which is used for read operation may also be used as detection means.

Alternatively, as a simpler detection method, the test terminal may not be provided, and the node may be fixed to a ground potential in a chip. In this case, when a similar test is performed, the presence or absence of a leakage can be detected by checking a power source current of an external power source which is supplied to the bit line voltage applying section 15 or the leakage test voltage applying section 17.

### Second Embodiment

Hereinafter, an overview of a semiconductor memory device according to a second embodiment of the present disclosure will be described with reference to the drawings. The semiconductor memory device of this embodiment is obtained by adding to a conventional semiconductor memory device a switch between the bit line voltage applying section and the main bit lines and between the main bit lines and the sense amplifier circuit, thereby making it possible to easily detect a leakage current between neighbor main bit lines. Detection operation is performed by using voltage detecting means (e.g., a sense amplifier circuit, etc.) to determine a change in voltage from a precharge level when a bit line to be detected is precharged to a desired voltage. By performing such detection operation, the presence or absence of leakage between main bit lines is detected.

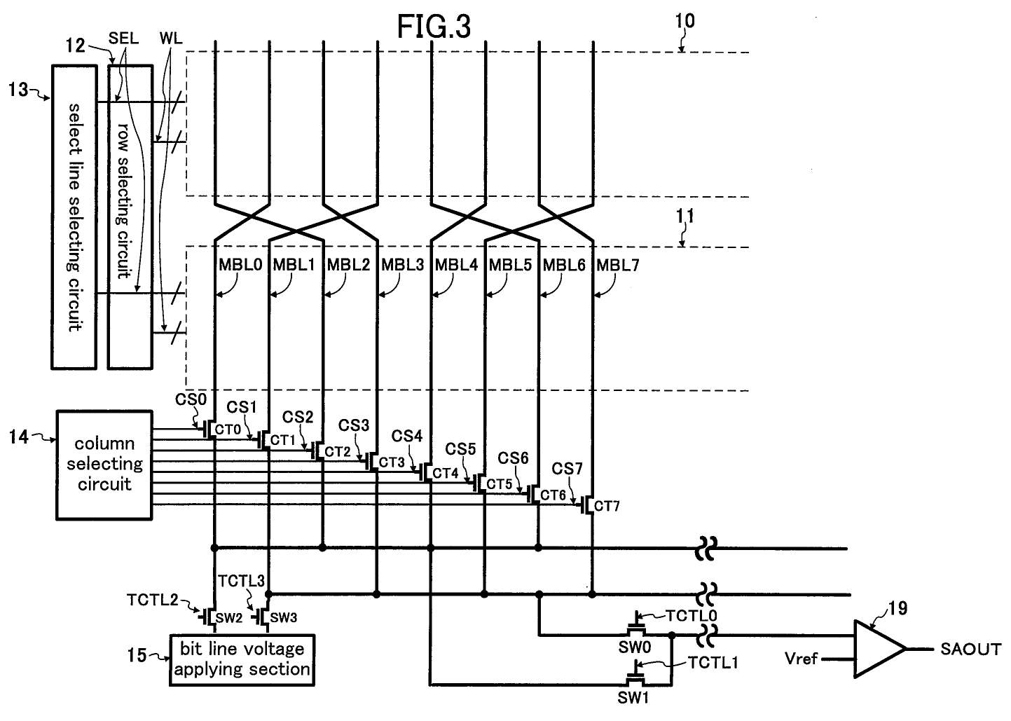

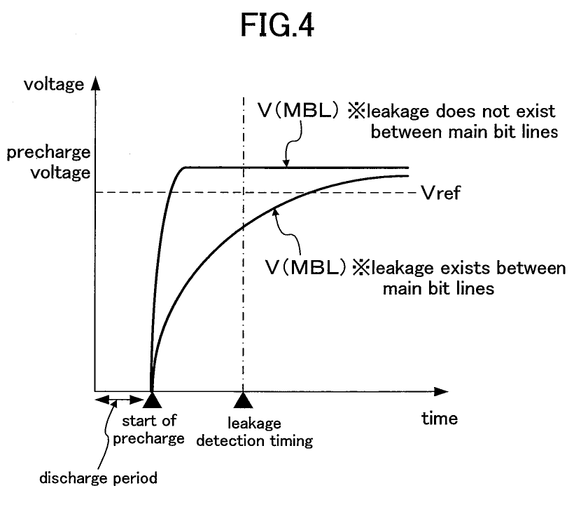

FIG. 3 is a diagram showing an arrangement of the semiconductor memory device of the second embodiment of the present disclosure. FIG. 4 is a voltage waveform for showing leakage detecting operation in the semiconductor memory device of FIG. 3.

Hereinafter, as an example, a method of testing a leakage between main bit lines MBL1, MBL2 and MBL3 neighboring a main bit line MBL0 will be mainly described. It would be easily inferred from the analogy of the description which follows that the method is also applicable to the other bit lines.

In FIG. 3, initially, all column selecting transistor select signals CS0 to CS7 and all control signals TCTL0 to TCTL3 are caused to take a logical value of “1,” whereby all main bit lines MBL0 to MBL7 are connected to a bit line voltage applying section 15. In this case, all the main bit lines are discharged to a ground potential by the bit line voltage applying section 15 (in FIG. 4, “discharge period”).

Thereafter, the column selecting transistor select signals CS1 to CS7 and the control signals TCTL0 and TCTL3 are caused to take a logical value of “0” so that a desired precharge voltage is applied by the bit line voltage applying section 15 only to the main bit line MBL0 to be subjected to leakage detection.

Thereafter, the bit line voltage applying section 15 is activated to start precharge operation (in FIG. 4, “start of precharge”). During this time, a precharge voltage level of MBL0 and a reference voltage Vref are input to a sense amplifier circuit 19, which performs comparison operation after a predetermined period of time has passed (in FIG. 4, “leakage detection timing”). Here, if there is a short-circuit failure between the main bit line MBL0 to be subjected to leakage detection and its neighbor main bit lines MBL1, MBL2 and MBL3, a precharge current leaks into the short-circuited main bit line, so that the parasitic capacitance is charged. Therefore, it takes a long time to reach a desired precharge voltage level as indicated by “V (MBL) leakage exists between main bit line” in FIG. 4.

When there is not a short-circuit failure between main bit lines, precharge operation is completed at a normal timing as shown in FIG. 4 (“V (MBL) leakage does not exist between main bit lines). Thus, the presence or absence of a leakage between main bit lines can be detected by determining a change in voltage from a precharge level using voltage detecting means, such as a sense amplifier circuit or the like.

Although the method of using a sense amplifier circuit as leakage current detecting means has been described as a method of detecting a leakage current, the detection method is not limited to this. For example, another voltage detecting means may be additionally provided in a chip so that the presence or absence of a leakage can be detected based on an output thereof.

Also, methods and timings of discharging and precharging main bit lines are not limited to those described above. When there is a short-circuit failure between a main bit line to be subjected to leakage detection and its neighbor main bit line, if an arrangement or operation is provided to detect the leakage current as a potential difference using voltage detecting means, such as a sense amplifier circuit or the like, the presence or absence of a leakage can be detected between main bit lines.

The semiconductor memory device according to the present disclosure is capable of easily determining the presence or absence of a leakage between main bit lines and is useful as, for example, a semiconductor memory device having a memory array arrangement in which a plurality of main bit lines intersect. The semiconductor memory device according to the present disclosure is also applicable to applications, such as detection of a leakage between data buses when the data buses are caused to intersect so as to reduce crosstalk.

What is claimed is:

1. A semiconductor memory device having a memory cell region in which a plurality of memory cells are arranged in a matrix extending in a row direction and in a column direction, the memory cell region being divided into a plurality of sectors each including a predetermined number of rows, the device comprising:
a column selecting circuit for selecting a column in the memory cell region;
a row selecting circuit for selecting a row in the memory cell region;
a plurality of word lines provided for respective rows of the memory cells and connected to the row selecting circuit;
a plurality of main bit lines extending in the column direction and connected to respective column selecting transistors controlled by the column selecting circuit;
a plurality of sub-bit lines provided in each of the sectors and extending in the column direction;
a plurality of selecting transistors provided for the respective sub-bit lines, for electrically connecting or disconnecting the respective main bit lines and the respective sub-bit lines;
a plurality of select lines extending in the row direction, for applying a voltage for switching conductive and non-conductive states of the respective selecting transistors, to control electrodes of the respective selecting transistors; and
a select line selecting circuit for driving the select lines,
wherein the row selecting circuit selects a word line connected to a memory cell to be read out,
the plurality of main bit lines have an intersecting region between the sectors, the plurality of main bit lines intersecting at one or more points in the intersecting region, and
the semiconductor memory device is configured to be able to supply different voltages to neighbor ones of the main bit lines in each of the sectors.

2. The semiconductor memory device of claim 1, further comprising:
switch circuits provided for the respective main bit lines, for supplying different voltages to neighbor ones of the main bit lines.

3. The semiconductor memory device of claim 1, further comprising:
a current detecting circuit for detecting a current passing between neighbor ones of the main bit lines.

4. The semiconductor memory device of claim 2, further comprising:
a current detecting circuit for detecting a current passing between neighbor ones of the main bit lines.

5. The semiconductor memory device of claim 1, further comprising:
a terminal for detecting a current passing between neighbor ones of the main bit lines.

6. The semiconductor memory device of claim 2, further comprising:
a terminal for detecting a current passing between neighbor ones of the main bit lines.

7. The semiconductor memory device of claim 2, further comprising:
a voltage applying section connected to the switch circuit.

8. The semiconductor memory device of claim 2, further comprising:
a switch circuit selecting circuit for controlling the switch circuit.
